(19) United States
(12) Patent Application Publication
(10) Pub. No.: US 2021/0407796 A1
(43) Pub. Date: Dec. 30, 2021

(54) METHOD FOR MANUFACTURING SEMICONDUCTOR AND MULTI-PIECE DEPOSITION DEVICE

(71) Applicant: CHANGXIN MEMORY TECHNOLOGIES, INC., Hefei (CN)

(72) Inventors: Hsiang-Tung TSENG, Hefei (CN); Xiankun DUAN, Hefei (CN); Ruochen REN, Hefei (CN)

(21) Appl. No.: 17/472,825

(22) Filed: Sep. 13, 2021

Related U.S. Application Data
(63) Continuation of application No. PCT/CN2021/082445, filed on Mar. 23, 2021.

(30) Foreign Application Priority Data
Apr. 13, 2020 (CN) 202010287337.0

(51) Int. Cl. H01L 21/02; H01J 37/32

(52) U.S. Cl. CPC H01L 21/02274; H01J 2237/332; H01J 37/32082; H01J 37/32449

(57) ABSTRACT

Examples of the application provide a method for manufacturing a semiconductor and a multi-piece deposition device. The method for manufacturing the semiconductor includes: performing a first-round deposition process on a substrate in the multi-piece deposition device; taking out the substrate after the first-round deposition process is completed; introducing an auxiliary gas into the multi-piece deposition device, and forming plasmas from the auxiliary gas; placing a substrate to be deposited in the multi-piece deposition device; and performing a second-round deposition process on the substrate in the multi-piece deposition device. The auxiliary gas is introduced and converted into the plasmas in a time interval of waiting time between the first-round deposition process and the second-round deposition process.

### CROSS-REFERENCE TO RELATED APPLICATION

The present application is a U.S. continuation application of International Application No. PCT/CN2021/082445, filed on Mar. 23, 2021, which claims priority to Chinese Patent Application No. 202010287337.0, filed on Apr. 13, 2020. International Application No. PCT/CN2021/082445 and Chinese Patent Application No. 202010287337.0 are incorporated herein by reference in their entireties.

### TECHNICAL FIELD

The disclosure relates to the field of semiconductor manufacturing methods, and particularly to a semiconductor manufacturing method and a multi-piece deposition device.

### BACKGROUND

At present, volumes of devices for substrate deposition are gradually enlarged. A large-volume deposition device, i.e., a multi-piece deposition device, can perform a deposition process on a relatively large number of substrates at one time, and thus is higher in deposition efficiency. In a related art, a radio frequency compensation function is usually used to shorten time for generating a radio frequency in a multi-piece deposition device.

However, the applicant finds that, for a multi-piece deposition device, even though deposition processes are continuously performed on substrates of each batch, a time interval between the deposition processes for the substrates of each batch is far longer than that of a single-piece deposition device. Consequently, the number of residual charges in the deposition device is greatly reduced, time for generating a radio frequency is still very long even though the radio frequency compensation function is used to shorten the time for generating the radio frequency, which severely affects the deposition efficiency of the multi-piece deposition device, and reduces the deposition efficiency of the substrate.

### SUMMARY

Examples of the disclosure provide a method for manufacturing a semiconductor and a multi-piece deposition device. An auxiliary gas is introduced in a time interval between a first-round deposition process and second-round deposition process performed by the multi-piece deposition device, and is converted into plasmas to increase the number of residual charges in the multi-piece deposition device, thereby shortening time for generating a radio frequency required by the deposition process and further improving the substrate production efficiency.

In order to solve the foregoing technical problem, examples of the disclosure provide a method for manufacturing a semiconductor, which may be applied to a multi-piece deposition device and includes the following operations: performing a first-round deposition process on a substrate in the multi-piece deposition device; taking out the substrate after the first-round deposition process is completed; introducing an auxiliary gas into the multi-piece deposition device, and forming plasmas from the auxiliary gas; placing a substrate to be deposited in the multi-piece deposition device; and performing a second-round deposition process on the substrate in the multi-piece deposition device.

Examples of the disclosure also provide a multi-piece deposition device, which may be applied to the semiconductor manufacturing method and include: an intake pipeline, configured to introduce a gas into the multi-piece deposition device, therein the gas including a purging gas, an auxiliary gas or a precursor; an exhaust pipeline, configured to discharge the gas in the multi-piece deposition device; a radio frequency power supply, configured to provide a radio frequency for the multi-piece deposition device; and a controller, configured to control a introduction of the auxiliary gas into the multi-piece deposition device by the intake pipeline and a turning on of the radio frequency power supply within first preset time, after the multi-piece deposition device completes a first-round deposition process and before a second-round deposition process is started.

### BRIEF DESCRIPTION OF THE DRAWINGS

FIG. 1 is a flowchart of a method for manufacturing a semiconductor involved in an example of the disclosure.

FIG. 2 is a schematic diagram of a multi-piece deposition device provided by an example of the disclosure.

FIG. 3 is a principle diagram of shortening time for generating a radio frequency involved in an example of the disclosure.

FIG. 4 is a schematic diagram of placing a substrate in a multi-piece deposition device involved in an example of the disclosure.

FIG. 5 is a schematic diagram of a corresponding state of a multi-piece deposition device when a preprocessing step is not performed in a method for manufacturing a semiconductor according to an example of the disclosure.

FIG. 6 is a schematic diagram of a corresponding state of a multi-piece deposition device when a preprocessing step is performed in a method for manufacturing a semiconductor according to an example of the disclosure.

FIG. 7 is a flowchart of a method for manufacturing a semiconductor involved in another example of the disclosure.

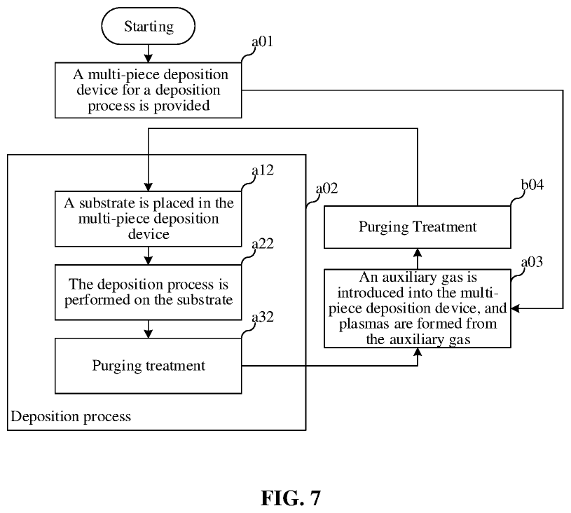

### DETAILED DESCRIPTION

At present, devices for substrate deposition are divided into single-piece deposition devices and multi-piece deposition devices. Compared with the single-piece deposition device, the multi-piece deposition device can perform a deposition process on a larger number of substrates at one time, and thus is higher in deposition efficiency. In the related art, a radio frequency compensation function is usually used to shorten time for generating a radio frequency in a multi-piece deposition device.

However, the application finds that a reaction space of a multi-piece deposition device is far larger than a reaction space of a general single-piece deposition device, so that the multi-piece deposition device, compared with the single-piece deposition device, is a large-volume deposition device. Moreover, for a multi-piece deposition device, even though deposition processes are continuously performed on substrates of each batch, a time interval between the deposition processes for the substrates of each batch is far longer than that of a single-piece deposition device. Specifically, due to the design of the multi-piece deposition device (more than 100 substrates are required to be transferred every time when a deposition process is performed), even though the processes are continuously performed on each batch, the time interval (transferring the substrate+pressure change in non-main process steps+gas purging treatment after main process steps) is longer than 60 minutes, while the time interval of the single-piece deposition device is usually shorter than 7 minutes. Consequently, the number of residual charges in the deposition device is greatly reduced, time for generating a radio frequency is still long even though a radio frequency compensation function is used to shorten the time for generating the radio frequency, which severely affects the deposition efficiency of the multi-piece deposition device, and reduces the deposition efficiency of the substrate.

In order to solve the foregoing problem, an example of the disclosure provides a method for manufacturing a semiconductor, which is applied to a multi-piece deposition device and includes the following operations. A first-round deposition process is performed on a substrate in the multi-piece deposition device; the substrate is taken out after the first-round deposition process is completed; an auxiliary gas is introduced into the multi-piece deposition device, and plasmas are formed from the auxiliary gas; a substrate to be deposited is placed in the multi-piece deposition device; and a second-round deposition process is performed on the substrate in the multi-piece deposition device.

In order to make the objectives, technical solutions and advantages of the examples of the disclosure clearer, each example of the disclosure will be described below in combination with the drawings in detail. However, those of ordinary skill in the art can understand that, in each example of the disclosure, many technical details are proposed to make readers to better understand the disclosure. However, the technical solutions claimed by the disclosure may also be implemented even without these technical details and various variations and modifications made based on each of the following example. Division of each of the following examples is for convenient description and should not form any limit to specific example of the disclosure. Each example can be combined and refer to each other without conflicts.

The following specifically describes implementation details of the method for manufacturing the semiconductor of the example.

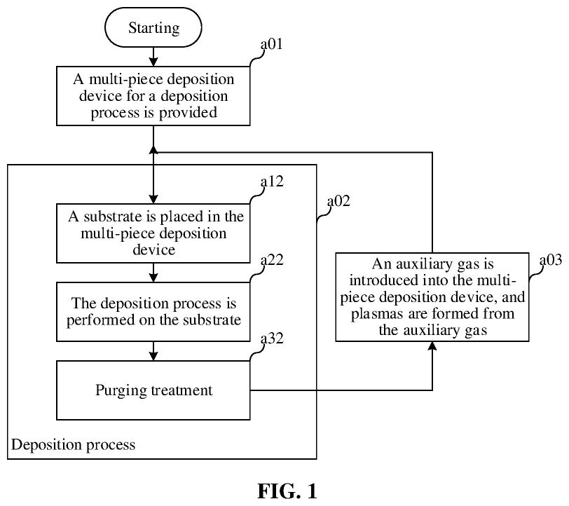

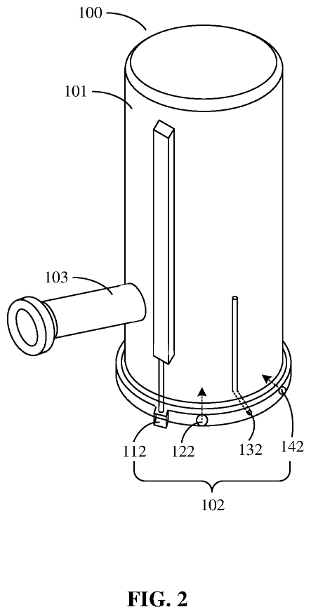

FIG. 1 shows a specific flowchart of the method for manufacturing the semiconductor of an example of the disclosure, and FIG. 2 shows the multi-piece deposition device. The flow includes the following operations.

At step a01, a multi-piece deposition device for a deposition process is provided. The multi-piece deposition device 100 includes the following.

A reaction chamber 101 is configured to place a substrate that is placed in the multi-piece deposition device, and configured to perform the deposition process on multiple substrates in the multi-piece deposition device. Since the deposition process on the substrate is performed in the reaction chamber 101, those skilled in the art know that a gas subsequently introduced into the multi-piece deposition device 100 is practically introduced into the reaction chamber 101. The substrate includes a raw material for the deposition process, such as a wafer and a silicon chip. Specifically, when the substrate is in the reaction chamber 101, and after the radio frequency power supply is turned on, the deposition process is performed on the substrate in the reaction chamber 101.

It is to be noted that, compared with the single-piece deposition device, a container volume of the multi-piece deposition device 100 is larger, and the reaction chamber 101 thereof may accommodate more substrates. Moreover, the multi-piece deposition device in the example may be applied not only to deposition of multiple substrates, and those skilled in the art know that the multi-piece deposition device can also be applied to deposition of a single substrate, namely the multi-piece deposition device disclosed in the example does not limit the number of substrates applied to the device.

The intake pipeline 102 is configured to introduce a gas into the multi-piece deposition device 100.

The gas introduced through the intake pipeline 102 includes a precursor required by the deposition process (including a first precursor required by a first-round deposition process and a second precursor required by a second-round deposition process), an auxiliary gas introduced between the first-round deposition process and the second-round deposition process and a purging gas for purging; therein the purging gas at least includes at least one N₂ or an inert gas; and the precursor is a gaseous material required to be deposited on the substrate; and the auxiliary gas includes at least one of oxygen or ozone.

Specifically, the intake pipeline 102 includes a first intake pipeline 112, a second intake pipeline 132 and a third intake pipeline 142.

Between the first-round deposition process and second-round deposition process performed by the multi-piece deposition device 100, the first intake pipeline 112 is configured to introduce the auxiliary gas into the multi-piece deposition device 100; and when the multi-piece deposition device 100 performs the deposition process, the second intake pipeline 132 is configured to introduce the precursor into the multi-piece deposition device 100; and the third intake pipeline 142 is configured to introduce the purging gas into the multi-piece deposition device 100.

It is also to be noted that, in present example, the intake pipeline 102 may further include a fourth intake pipeline 122, and the fourth intake pipeline 122 is configured to introduce a protective gas to maintain the multi-piece deposition device 100. In the present example, the protective gas is N₂ or an inert gas. In other examples, the protective gas may also be a cleaning gas for cleaning the multi-piece deposition device, for example, hydrogen fluoride.

The exhaust pipeline 103 is configured to discharge the gas in the multi-piece deposition device 100.

The radio frequency power supply (not shown in the figure) is configured to provide a radio frequency for the multi-piece deposition device 100.

The controller (not shown in the figure) is configured to, after the multi-piece deposition device 100 completes the first-round deposition process and before the second-round deposition process is started, control the intake pipeline 102 to introduce the auxiliary gas into the multi-piece deposition device 100 and turn on the radio frequency power supply within a first preset time. Therein the auxiliary gas is converted into plasmas within the first preset time, so that the number of residual charges in the reaction chamber 101 is increased, thereby time subsequently spent on generation of the radio frequency is shortened.

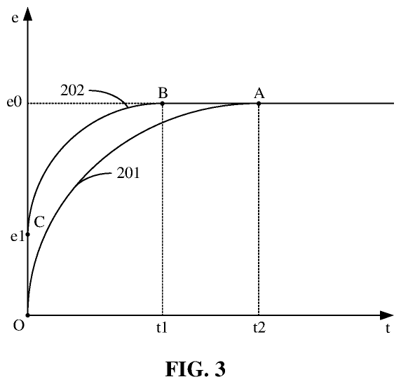

A principle of shortening the time for generating the radio frequency through the number of the residual charges refers to FIG. 3.

In FIG. 3, the X axis represents turning-on time of the radio frequency power supply, and the Y axis represents a charge number in the reaction chamber. There is made such a hypothesis that, when the charge number in the reaction chamber reaches e0, the radio frequency required by the deposition process is generated and the precursor is ionized to form plasmas for substrate deposition.

A curve 201 represents that, when an initial charge number of the reaction chamber is 0 (namely an initial point of the curve is O), after the radio frequency power supply is turned on, the charge number in the reaction chamber reaches e0 after time t2 (an abscissa of a point A in the curve 201), and in such case, time t2 passes from turning-on of the radio frequency power supply to generation of the radio frequency. A curve 202 represents that, when the initial charge number of the reaction chamber is e1 (namely an initial point of the curve is C), after the radio frequency power supply is turned on, the charge number in the reaction chamber reaches e0 after time t1 (an abscissa of a point B in the curve 202), and in such case, time t1 passes from turning-on of the radio frequency power supply to generation of the radio frequency. It can be seen from comparison between the curve 201 and the curve 202 that, if the charge number of initial charges in the reaction chamber is larger, the time from turning-on of the radio frequency power supply to generation of the radio frequency is shorter.

Still referring to FIG. 1, step a02 is a deposition process step, and step a02 specifically includes step a12, step a22 and step a32, described as follows.

At step a12, a substrate is placed in the multi-piece deposition device.

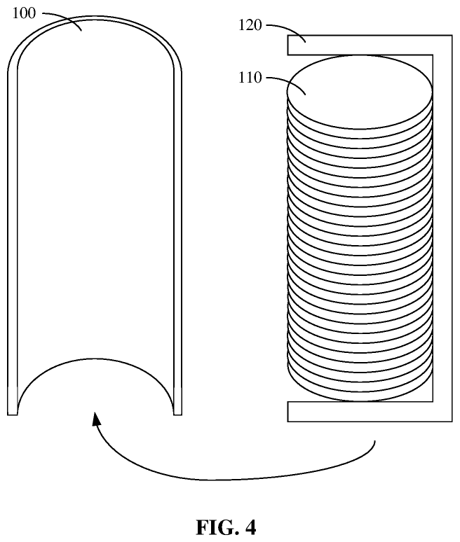

Referring to FIG. 4, multiple substrates 110 are stacked in a bearing mean 120, and the substrates 110 are placed in the multi-piece deposition device 100 through the bearing mean 120. The multi-piece deposition device 100 deposits the multiple substrates 110 in a round of deposition process, and in such case, even though two rounds of deposition processes are continuously performed, a lot of time is still required to be spent on transferring and stacking the substrates 110, so that the residual charges in the reaction chamber of the multi-piece deposition device 100 are lost, namely the initial charge number in the reaction chamber of the multi-piece deposition device 100 is relatively small when the next round of deposition process is started, generation of the radio frequency is retarded, thereby the yield of substrate products is affected.

It is to be noted that, when the substrate 110 is placed in or taken out of the multi-piece deposition device 100, pressure in the multi-piece deposition device 100 is more than or equal to 760 torr.

At step a22, the deposition process is performed on the substrate.

Specifically, the first-round deposition process is performed on the substrate. It is to be noted that the first-round deposition process performed on the substrate 110 by the multi-piece deposition device 100 does not refer in particular to a first round of deposition process after the substrate 110 is placed in the multi-piece deposition device 100, and any round of deposition process performed on the substrate 110 by the multi-piece deposition device 100 can be considered as the first-round deposition process.

The first precursor is introduced into the reaction chamber 101, and the radio frequency power supply is turned on to ionize the first precursor in the reaction chamber 101 to form plasmas. When the number of the plasmas reaches a certain degree, the radio frequency required by the deposition process is generated in the reaction chamber 101. After second preset time, the radio frequency power supply is turned off, the deposited substrate is taken out, and the purging gas is introduced into the reaction chamber 101 for purging treatment. The second preset time refers to time required from turning-on of the radio frequency power supply to completion of the first-round deposition process for the substrate in the reaction chamber 101.

It is to be noted that, when the deposition process is performed on the substrate in the reaction chamber 101, pressure of the reaction chamber 101 is less than 1 torr.

At step a32, purging treatment is performed.

Specifically, the purging gas is introduced into the reaction chamber 101 for purging treatment. The purging gas is introduced into the reaction chamber 101 to replace a gas generated by the deposition process in the reaction chamber 101 to avoid the influence of the remaining gas on a next round of deposition process.

After step a32 is completed, namely step a02 is completed, the multi-piece deposition device 100 completes the steps of the first-round deposition process, and before the multi-piece deposition device 100 performs steps of the second-round deposition process, namely between the steps of the two rounds of deposition processes performed by the multi-piece deposition device 100, the method further includes the following operations.

At step a03, an auxiliary gas is introduced into the multi-piece deposition device, and plasmas are formed from the auxiliary gas.

It is to be noted that the auxiliary gas is ionized to form the plasmas for a purpose of increasing the number of the residual charges in the multi-piece deposition device. Those skilled in the art can understand that, since residual charges may correspondingly be generated when the plasmas are formed in the multi-piece deposition device, increasing the total number of the residual charges in the multi-piece deposition device may increase a generation speed of the radio frequency in the multi-piece deposition device.

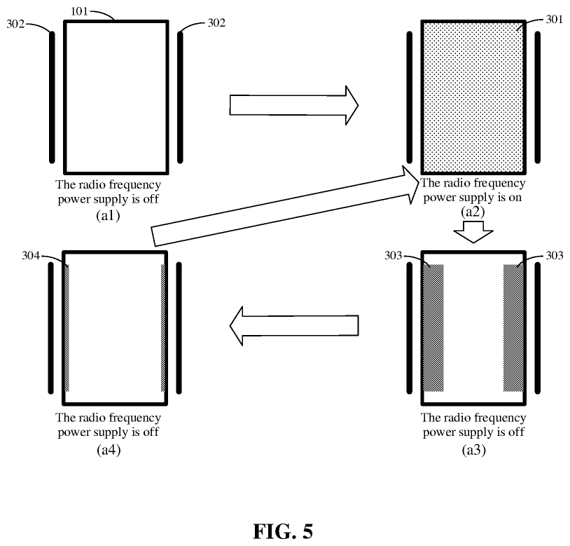

If step a03 is not executed, a state corresponding to each step in the reaction chamber 101 refers to the flow in FIG. 5, described as follows.

(a1) of this figure represents that the multi-piece deposition device has yet not started the deposition process, there are no residual charges and plasmas in the reaction chamber 101, the radio frequency power supply is off and electrodes 302 are in an off-working state.

(a2) of this figure represents that, when the multi-piece deposition device performs the deposition process, the radio frequency power supply is in an on state, the radio frequency power supply is applied to the reaction chamber 101 through the electrodes 302 and the reaction chamber 101 is filled with a plasma-state precursor 301.

Since there are no residual charges in the reaction chamber 101 in (a1) of this figure, time for generating the radio frequency in the first round passes from (a1) of this figure to (a2) of this figure is long.

After the deposition process is completed, the radio frequency power supply is turned off, remaining plasmas in the reaction chamber 101 are purged. In such case, there are still residual charges 303 generated by generation of the plasmas on a sidewall, close to the electrode 302, of the reaction chamber 101, as shown in (a3) of this figure.

Since a large number of substrates are required to be transferred when the multi-piece deposition device performs a round of deposition process, even though two adjacent rounds of deposition processes are continuously performed, waiting time (silicon chip transfer time, pressure change time and gas purging treatment time) is still long, namely a small number of residual charges remain in the reaction chamber 101 of the multi-piece deposition device after the radio frequency power supply is turned off in the first-round deposition process. That is, in a process from (a3) of this figure where the radio frequency power supply is off to (a2) of this figure where the radio frequency power supply is on, because the multi-piece deposition device is too large, there may be an intermediate process from (a3) to (a4) of this figure and then to (a2) of this figure. Specifically, since the waiting time is relatively long, the number of the residual charges in the reaction chamber 101 gradually decreases, and the residual charges gradually decrease to few charges 304 shown in (a4) of this figure. In such case, since the number of the initial charges is relatively small, a process from (a4) to (a2) of this figure is equivalent to the process from (a1) to (a2) of this figure, namely the time for generating the radio frequency in the subsequent process is still long.

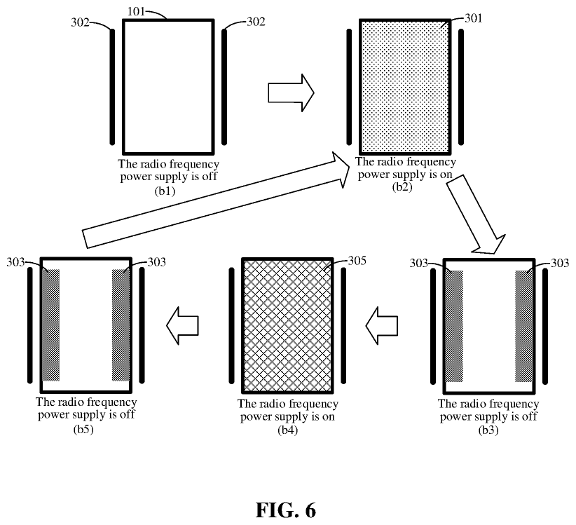

If step a03 is executed, the state corresponding to each step in the reaction chamber 101 refers to the flow in FIG. 6, described as follows.

Between the steps of the two rounds of deposition processes, namely in a process from (b3) to (b2) of the figure, the auxiliary gas is introduced into the multi-piece deposition device. Detailed descriptions are made in the example with oxygen as an example.

(b4) of the figure represents that oxygen is introduced into the reaction chamber 101 and the radio frequency power supply is turned on to ionize oxygen into oxygen plasmas 305. After preset time, the radio frequency power supply is turned off. In such case, the residual charges 303 in the reaction chamber 101 do not decrease, and a state of the reaction chamber 101 like the state in (b3) or (b5) of the figure is formed. When a next round of deposition process is performed, there are a relatively large number of residual charges 303 in the reaction chamber 101, so that the radio frequency may be generated easily.

After step a03 is completed, step a02 is continued to be executed. In such case, the introduced precursor is the second precursor, and the second-round deposition process is performed on the substrate in the multi-piece deposition device 100. Therein, third preset time refers to the time required from turning-on of the radio frequency power supply to completion of the first-round deposition process for the substrate in the reaction chamber 101.

It is to be noted that the first precursor may be the same as the second precursor or different. If the first precursor is the same as the second precursor, it indicates that the same material is deposited on the substrate in the first-round deposition process and the second-round deposition process. If the first precursor is different from the second precursor, it indicates that different materials are deposited on the substrate in the first-round deposition process and the second-round deposition process. In addition, a relationship between the second preset time (for execution of the first-round deposition process) and the third preset time (for execution of the second-round deposition process) is not limited in present example, and those skilled in the art should know that the second preset time and the third preset time are specifically set according to different deposition precursors. It is also to be noted that the first-round deposition process and the second-round deposition process may be multiple deposition processes performed on substrates of the same batch or deposition processes performed on substrates of different batches.

It is to be noted that, in the present example, after the second-round deposition process is performed on the substrate in the multi-piece deposition device 100, the method further includes that: the multi-piece deposition device 100 further performs multiple rounds of deposition processes; and between two rounds of deposition processes performed by the multi-piece deposition device 100, the auxiliary gas is introduced into the reaction chamber 101 of the multi-piece deposition device 100, and the radio frequency power supply is turned on to ionize the auxiliary gas to form plasmas; and after the first preset time, the radio frequency power supply is turned off.

It is also to be noted that the first-round deposition process and second-round deposition process introduced in the present example do not refer to a first round of deposition process and a second round of deposition process. Those skilled in the art should know that any round of deposition process performed by the multi-piece deposition device 100 during deposition may be considered as the first-round deposition process while a next round of deposition process is considered the second-round deposition process, and contents involving addition of a preprocessing step between two rounds of deposition processes shall fall within the scope of protection of the disclosure.

The above steps are divided only for clear description. During implementation, the steps can be combined into one step, or some steps may be split into multiple steps, and any solution including the same logical relationship falls within the scope of protection of the disclosure. Adding insignificant modifications to the flow or introducing insignificant designs without changing the core design of the flow falls within the scope of protection of the disclosure.

According to the present example, the auxiliary gas is introduced during a time interval of plasma deposition performed by the multi-piece deposition device, and is converted into the plasmas to increase the number of the residual charges in the multi-piece deposition device, thereby shortening the time for generating the radio frequency required by the deposition process and further improving the substrate deposition efficiency.

Another example of the disclosure relates to a semiconductor manufacturing method. The example is roughly the same as the previous example. The difference is that the flow is further optimized in the present example.

The following specifically describes implementation details of the semiconductor manufacturing method of the example. Parts the same as or corresponding to the previous example will not be elaborated below.

At step a01, a multi-piece deposition device for a deposition process is provided.

As a deposition process step, step a02 specifically includes step a12, step a22 and step a32. Specifically, at step a12, a substrate is placed in the multi-piece deposition device. At step a22, the deposition process is performed on the substrate. At step a32, purging treatment is performed.

At step a03, preprocessing is performed, and after preprocessing, a radio frequency power supply is turned off.

In the above example, after step a01 is completed, step a02 is continued to be executed. Unlike the above example, in the present example, after step a01 is completed, a03 is executed at first, and then step a02 is executed.

That is, before the multi-piece deposition device performs a first-round deposition process, the method further includes that: preprocessing is performed, namely an auxiliary gas is introduced into a reaction chamber 101, and the radio frequency power supply is turned on to ionize the auxiliary gas to form plasmas; and after preprocessing, the radio frequency power supply is turned off.

The number of residual charges in the reaction chamber 101 of the multi-piece deposition device is increased to shorten time for generating a radio frequency required by the first-round deposition process and further improve the substrate deposition efficiency.

In the present example, in each round after step a03 is completed and before step a02 is executed, step b04 is further included.

At step b04, purging treatment is performed.

Specifically, a purging gas is introduced into the reaction chamber 101 for purging treatment. A process thereof is similar to that at step a32. However, there is a specific requirement on time for purging in step b04, and the time for purging treatment is greater than 5 seconds and less than 1 minute. The time for purging is planned reasonably to ensure that the auxiliary gas in the multi-piece deposition device is completely purged without influencing the overall efficiency of the deposition process.

The above steps are divided only for clear description. During implementation, the steps can be combined into one step, or some steps may be split into multiple steps, and any solution including the same logical relationship falls within the scope of protection of the disclosure. Adding insignificant modifications to the flow or introducing insignificant designs without changing the core design of the flow falls within the scope of protection of the disclosure.

According to the present example, before the multi-piece deposition device performs the first-round deposition process, the auxiliary gas is introduced and converted into the plasmas to increase the number of the residual charges in the reaction chamber 101 of the multi-piece deposition device to shorten the time for generating the radio frequency required by the first-round deposition process and further improve the substrate deposition efficiency. Meanwhile, for preventing the influence of the remaining auxiliary gas on substrate production, purging treatment is performed on the reaction chamber 101 of the multi-piece deposition device before the deposition process is performed.

Another example of the disclosure provides a multi-piece deposition device. In the present example, the multi-piece deposition device is described with a furnace tube device as an example. The following specifically describes implementation details of the multi-piece deposition device of the present example.

Referring to FIG. 2, the multi-piece deposition device 100 includes a reaction chamber 101 configured to perform a deposition process on a substrate, as well as an intake pipeline 102, an exhaust pipeline 103, a radio frequency power supply and a controller.

The intake pipeline 102 is configured to introduce a gas into the multi-piece deposition device 100, therein, the gas including a purging gas, an auxiliary gas or a precursor. The exhaust pipeline 103 is configured to discharge the gas in the multi-piece deposition device 100. The radio frequency power supply (not shown in the figure) is applied to the multi-piece deposition device 100, and is configured to provide a radio frequency for the multi-piece deposition device 100. The controller (not shown in the figure) is configured to, after the multi-piece deposition device 100 completes a first-round deposition process and before a second-round deposition process is started, control the intake pipeline 102 to introduce the auxiliary gas into the multi-piece deposition device 100 and turn on the radio frequency power supply within a first preset time.

In the present example, the gas includes the precursor required by the deposition process, the auxiliary gas introduced between deposition process steps and the purging gas for purging. The precursor includes a gaseous material required to be deposited on the substrate. The auxiliary gas includes at least one of oxygen or ozone.

Specifically, the intake pipeline 102 includes a first intake pipeline 112, a second intake pipeline 132 and a third intake pipeline 142.

Between the first-round deposition process and second-round deposition process performed by the multi-piece deposition device 100, the first intake pipeline 112 is configured to introduce the auxiliary gas into the multi-piece deposition device 100. When the multi-piece deposition device 100 performs the deposition process, the second intake pipeline 132 is configured to introduce the precursor into the multi-piece deposition device 100. The third intake pipeline 142 is configured to introduce the purging gas into the multi-piece deposition device 100.

It is to be noted that, in the present example, the intake pipeline 102 may further include a fourth intake pipeline 122, and the fourth intake pipeline 122 is configured to introduce a protective gas to maintain the multi-piece deposition device 100. In the present example, the protective gas is N₂ or an inert gas. In another example, the protective gas may also be a cleaning gas for cleaning the multi-piece deposition device 100, for example, hydrogen fluoride.

Specifically, the radio frequency power supply is applied to an electrode on the reaction chamber 101. During the deposition process, when the radio frequency power supply is turned on, the precursor in the reaction chamber 101 is gradually ionized to form plasmas. Between two rounds of deposition processes, when the radio frequency power supply is turned on, the auxiliary gas in the reaction chamber 101 is converted into plasmas, and after the radio frequency power supply is turned off, there are a large number of residual charges in the reaction chamber 101, so that time for generating a radio frequency required by the deposition process during the deposition process is shortened, thereby the substrate deposition efficiency is improved.

In the present example, the controller further includes a purging module (not shown in the figure). The purging module (not shown in the figure) is configured to introduce the purging gas into the reaction chamber 101 for purging treatment after the first preset time and before the deposition process is started. Specifically, time for purging treatment may be greater than 5 seconds and less than 1 minute. The time for purging is planned reasonably to ensure that the auxiliary gas in the multi-piece deposition device is completely purged without influencing the overall efficiency of the deposition process.

It is to be noted that, in another example, the multi-piece deposition device further includes a detection component, configured to detect pressure of the reaction chamber; and a pressure regulation component, configured to regulate the pressure of the reaction chamber. Specifically, when the deposition process is performed on the substrate in the reaction chamber, the pressure of the reaction chamber is regulated to be less than 1 torr; and when the substrate is placed in or taken out of the multi-piece deposition device, the pressure of the multi-piece deposition device is regulated to be greater than 760 torr.

The example of the disclosure provides the following mounting manners for the detection component and the pressure regulation component, specifically as follows.

A first manner: the pressure of the multi-piece deposition device 100 is regulated manually. In this manner, an additional display panel is required to be mounted, the detection component is connected with the display panel, a specific numerical value of the pressure in the multi-piece deposition device 100 is displayed through the display panel after the detection component detects the pressure in the multi-piece deposition device 100, a worker refers to the numerical value to control to regulate the pressure in the multi-piece deposition device 100 if the pressure in the multi-piece deposition device 100 is required to be regulated.

A second manner: the multi-piece deposition device 100 implements automatic regulation. In this manner, both the detection component and the pressure regulation component are connected to the controller, the detection apparatus detects the pressure in the multi-piece deposition device 100 in real time, the detection component sends a control signal to the controller after detecting that the pressure in the multi-piece deposition device 100 is greater than or less than a preset value, and the controller, after receiving the control signal, controls the pressure regulation component to regulate the pressure in the multi-piece deposition device 100.

It is to be noted that each module involved in the present example is a logical module. In practical applications, a logical unit may be a physical unit or a part of a physical unit, or may be implemented as a combination of multiple physical units. In addition, for highlighting innovative parts of the disclosure, units related not so closely to the technical problem to be solved in the disclosure are not introduced in the present example, but this does not mean that there are no other units in the present example.

The above examples correspond to the present example, so that the present example can be matched with the above examples for implementation. The related technical details mentioned in the above examples are still effective in the present example, and the technical effects that may be achieved in the above examples may also be achieved in the present example. For reducing repetitions, elaborations are omitted here. Correspondingly, the related technical details mentioned in the present example may also be applied to the above examples.

According to the present example, the auxiliary gas is introduced and converted into the plasmas in a time interval of waiting time. In such a manner, the number of the residual charges in the reaction chamber is increased, and when a next round of deposition process is started, there are a relatively large number of residual charges in the reaction chamber and the radio frequency required by the deposition process may be generated fast, so that the time for generating the radio frequency is greatly shortened, thereby the substrate deposition efficiency is improved.

Those of ordinary skill in the art can understand that each example is a specific example implementing the disclosure, and in practical applications, various variations about the form and details can be made thereto without departing from the spirit and scope of the disclosure.

1. A method for manufacturing a semiconductor applied to a multi-piece deposition device, comprising:
performing a first-round deposition process on a substrate in the multi-piece deposition device;
taking out the substrate after the first-round deposition process is completed;
introducing an auxiliary gas into the multi-piece deposition device, and forming plasmas from the auxiliary gas;
placing a substrate to be deposited in the multi-piece deposition device; and
performing a second-round deposition process on the substrate in the multi-piece deposition device.

2. The method for manufacturing the semiconductor of claim 1, wherein the first-round deposition process comprises:
within a second preset time, introducing a first precursor into the multi-piece deposition device, and turning on a radio frequency power supply to ionize the first precursor to form plasmas; and
introducing a purging gas into the multi-piece deposition device for purging treatment.

3. The method for manufacturing the semiconductor of claim 1, wherein the second-round deposition process comprises:
within a third preset time, introducing a second precursor into the multi-piece deposition device, and turning on a radio frequency power supply to ionize the second precursor to form plasmas; and
introducing a purging gas into the multi-piece deposition device for purging treatment.

4. The method for manufacturing the semiconductor of claim 1, wherein the introduction of the auxiliary gas into the multi-piece deposition device and the formation of the plasmas from the auxiliary gas comprise:
introducing the auxiliary gas into the multi-piece deposition device; and
turning on a radio frequency power supply within a first preset time to ionize the auxiliary gas to form plasmas.

5. The method for manufacturing the semiconductor of claim 4, wherein the method further comprises, after performing the second-round deposition process on the substrate, performing multiple rounds of deposition processes in the multi-piece deposition device; and
between any two rounds of the deposition processes performed in the multi-piece deposition device, introducing the auxiliary gas into the multi-piece deposition device, and forming plasmas from the auxiliary gas within the first preset time.

6. The method for manufacturing semiconductor of claim 1, wherein the auxiliary gas comprises at least one of oxygen or ozone.

7. The method for manufacturing semiconductor of claim 2, wherein the auxiliary gas comprises at least one of oxygen or ozone.

8. The method for manufacturing semiconductor of claim 3, wherein the auxiliary gas comprises at least one of oxygen or ozone.

9. The method for manufacturing semiconductor of claim 4, wherein the auxiliary gas comprises at least one of oxygen or ozone.

10. The method for manufacturing semiconductor of claim 5, wherein the auxiliary gas comprises at least one of oxygen or ozone.

11. The method for manufacturing the semiconductor of claim 1, wherein the method further comprises introducing a purging gas for purging treatment, after introducing the auxiliary gas into the multi-piece deposition device and making the auxiliary gas form the plasmas and before performing the second-round deposition process on the substrate in the multi-piece deposition device.

12. The method for manufacturing semiconductor of claim 2, wherein a time for purging treatment is greater than 5 seconds and less than 1 minute.

13. The method for manufacturing semiconductor of claim 3, wherein a time for purging treatment is greater than 5 seconds and less than 1 minute.

14. The method for manufacturing semiconductor of claim 7, wherein a time for purging treatment is greater than 5 seconds and less than 1 minute.

15. A multi-piece deposition device, comprising:
an intake pipeline, configured to introduce a gas into the multi-piece deposition device, the gas comprising a purging gas, an auxiliary gas or a precursor;
an exhaust pipeline, configured to discharge the gas from the multi-piece deposition device;
a radio frequency power supply, configured to provide a radio frequency to the multi-piece deposition device; and
a controller, configured to control a introduction of the auxiliary gas into the multi-piece deposition device by the intake pipeline and a turning on of the radio frequency power supply within first preset time, after the multi-piece deposition device completes a first-round deposition process and before a second-round deposition process is started.

16. The multi-piece deposition device of claim 15, wherein the controller further comprises:
a purging module, configured to introduce the purging gas into the multi-piece deposition device for purging treatment after the first preset time and before starting the second-round deposition process.

17. The multi-piece deposition device of claim 15, wherein the intake pipeline at least comprises:
a first intake pipeline, a second intake pipeline and a third intake pipeline;
wherein the first intake pipeline is configured to introduce the auxiliary gas into the multi-piece deposition device; the second intake pipeline is configured to introduce the precursor into the multi-piece deposition device; and the third intake pipeline is configured to introduce the purging gas into the multi-piece deposition device.

18. The multi-piece deposition device of claim 15, wherein the multi-piece deposition device further comprises: a detection component, configured to detect pressure inside the multi-piece deposition device, and a pressure regulation component, configured to regulate the pressure of the multi-piece deposition device.
